(19) United States
(12) Patent Application Publication
(10) Pub. No.: US 2007/0267941 A1
(43) Pub. Date: Nov. 22, 2007

(54) HOLDER FOR A SENSOR

(75) Inventors: Oliver Eidel, Moeglingen (DE); Stefan Triebl, Muehlacker (DE); Heinrich Gotzig, Heilbronn (DE)

Correspondence Address: BRINKS HOFER GILSON & LIONE, P.O. BOX 10395, CHICAGO, IL, 60610, US

(73) Assignee: Valeo Schalter und Sensoren GmbH, Bietigheim-Bissingen (DE)

(21) Appl. No.: 11/830,110

(22) Filed: Jul. 30, 2007

Related U.S. Application Data
(63) Continuation of application No. PCT/EP05/12125, filed on Nov. 11, 2005.

(30) Foreign Application Priority Data
Jan. 28, 2005 (DE) 10 2005 005 331.9

(51) Int. Cl. H01L 41/053

(52) U.S. Cl. 310/311

(57) ABSTRACT

The present disclosure relates to a holder for a sensor, particularly an ultrasound sensor for a parking assist system, including a sleeve-shaped body, into which the sensor can be inserted via an insertion opening, and which a fastening section for fastening the holder to a vehicle part. A cage is provided between the sleeve-shaped body and the sensor. This cage fixes the sensor inside the sleeve-shaped body both in the axial direction as well as in the radial direction.

### CROSS-REFERENCE TO RELATED APPLICATIONS

This application is a continuation of International Application No. PCT/EP2005/012125 filed on Nov. 11, 2005, which claims the benefit of German Patent Application No. 10 2005 005 331.9, filed Jan. 28, 2005. The disclosures of the above applications are incorporated herein by reference.

### FIELD

The invention relates to a holder for a sensor, in particular an ultrasound sensor for a parking assistance system.

### BACKGROUND

The statements in this section merely provide background information related to the present disclosure and may not constitute prior art.

Many such holders are known and serve to fasten the ultrasound sensor, with which ultrasonic signals are sent and received again, in the region of the bumper of a vehicle. For that purpose, the holder is inserted into a suitable opening on the vehicle and fixed there. Moreover, the holder serves not only to receive the ultrasound sensor but also to hold it positionally correctly, so that the ultrasonic signals sent will be emitted in the desired direction, and only ultrasonic signals reflected from certain directions can be received again.

For different vehicles and installation conditions, differently designed ultrasound sensors are used. These may for instance be ultrasound sensors whose plug-and-socket connection protrudes axially from the rear end of the ultrasound sensor, in other words diametrically opposite the diaphragm; such ultrasound sensors may have a large diameter and be quite long. Other ultrasound sensors have a plug-and-socket connection which protrudes orthogonally, that is, radially from the sensor housing; these ultrasound sensors have a smaller diameter and are shorter, but they require access from the side to the plug-and-socket connection.

### SUMMARY

According to the present disclosure, a holder is provided, in that between the tubular body and the sensor, a cage is provided, which fixes the sensor in both the axial direction and the radial direction in the tubular body.

With the holder of the present disclosure, it thus becomes possible to fasten differently designed sensors on the vehicle positionally correctly and in the correct position, that is, in the correct orientation both axially and radially, without necessitating that a plurality of holders be furnished for that purpose. Either the sensor is inserted into the holder, or the sensor is provided with a cage, and the cage, with the inserted sensor, is fastened in the holder. The cage thus serves as an adapter, so as to position the sensor, having different and in particular smaller dimensions, in the holder and fasten it securely.

This makes it possible not only for different sensors from the same manufacturer but also for sensors from different manufacturers to be mounted easily on the vehicle, thus expanding the range of products the vehicle manufacturer can offer because it is now possible for the manufacturer to offer different parking assistance systems.

In an advantageous refinement, it is provided that the tubular body and/or the cage has a recess, which is peripherally open toward the insertion opening, for receiving an electrical connection that for instance protrudes radially from the sensor. By means of this recess, the possibility is created that both sensors with axially rearward-protruding connections and sensors with connections protruding radially to the side can be fastened in the holder. The recess is dimensioned such that even sensors with different-sized electrical connections can be fixed in the holder.

Preferably, the cage has at least one pivot arm, extending in the longitudinal direction and having a free end, and the pivot arm has a receiving opening for receiving a pawl that protrudes radially from the sensor. This pivot arm serves to secure the sensor, inserted into the cage, against falling out counter to the insertion direction, or in other words to secure it against falling out to the rear. The sensor has at least one radially protruding pawl, which after the insertion of the sensor into the cage snaps into a receiving opening. Upon insertion of the sensor into the cage, the pivot arm is pivoted radially outward slightly, until the receiving opening snaps onto the pawl, whereupon the pivot arm pivots back into its outset position. In this outset position of the pivot arm, the pawl is securely engaged from behind and prevents the sensor from being pulled off or out or from falling out.

In a refinement, it is provided that the cage, on its side diametrically opposite the insertion opening of the tubular body, has a radially inward-protruding bracing ring. This bracing ring serves as a stop for the sensor to be inserted into the cage, so that the sensor has a defined inserted position. In this inserted position, the sensor is held, as described above, by means of the pivot arm and its pawl. The region of the sensor having the diaphragm extends through the bracing ring and is braced with a shoulder on the bracing ring. This shoulder is often equipped with or lined by a soft material, and acoustical decoupling between the housing of the sensor and the holder is accomplished as a result.

Further security, particularly against twisting, is created by provided that the bracing ring, on its side toward the interior of the cage, has retention knobs for the shoulder of the sensor. These retention knobs dig into the elastic region of the shoulder, for instance, and prevent the sensor from twisting in the holder, even if only slightly.

Preferably, the free end of the pivot arm is provided with a radially outward-protruding pawl, which is lockable into a receptacle provided on the tubular body. This pawl provided on the cage serves to keep the cage captive in the interior of the holder once the sensor has been inserted into the cage. The pawl provided on the free end of the pivot arm extends through a receptacle in the tubular body. To enable mounting the cage, with the sensor inserted, as simply as possible in the tubular body, the free end of the pivot arm protrudes past the rear end of the sensor, so that the free end can deflect inward when the cage is inserted into the tubular body. As soon as the cage is in the correct position, the free end of the pivot arm, having been bent inward, snaps radially outward.

Preferably, the free end of the pivot arm is provided with a radially outward-protruding boundary face, which comes to rest on the inside face of the tubular body. This boundary face defines the location of the end of the pivot arm once the cage has been inserted into the tubular body. The free end of the pivot arm can thus be pivoted radially outward at most far enough that the boundary face rests on the inner face of the tubular body. This assures that the pivot arm will not pivot radially outward too far and prevents the locking of the sensor in the cage from possibly being undone. Thus the boundary face provides security for locking of the sensor in the cage.

One exemplary embodiment furthermore provides that the cage has a radially outward-protruding insertion limiter, which comes to rest on the edge of the insertion opening of the tubular body. These insertion limiters have the task of assuring the correct position of the cage in the tubular body in the axial direction. The cage is inserted far enough into the tubular body that the insertion limiters rest on the edge of the insertion opening. In this position, the pawl on the free end of the pivot arm then also engages the receptacle intended for it in the tubular body.

In still another embodiment, the cage has radially outward-protruding ribs, which extend in the longitudinal direction and rest on the inner wall of the tubular body. These ribs serve to brake the sensor, which has smaller dimensions, in the holder in such a way that it is positioned without play and in a defined way. The dimensions of the ribs are selected such that they correspond to the differences in dimensions of the various sensors.

Simple manipulation of the holder of the disclosure is attained by providing that the cage is embodied in one piece. The sensor having smaller dimensions is inserted into this one-piece cage, and the cage, with the sensor inserted, is then positioned like a one-piece component or like a larger sensor in the holder. Accordingly, it is unnecessary for a plurality of components to be disposed on the sensor. The cage has fastening elements that correspond in type and position to the fastening elements of the larger sensor.

The disclosure also relates to a method for fastening a sensor in a holder, in which according to the disclosure, a cage that has one or more of the above characteristics is fastened to the sensor, and then the cage is locked with the sensor in the holder, thereby assuring the fastening of the sensor in the cage.

Further advantages, characteristics and details of the disclosure will become apparent from the dependent claims as well as from the ensuing description, in which in conjunction with the drawings a particularly preferred exemplary embodiment is described in detail. The characteristics shown in the drawings and recited in the claims and mentioned in the specification may be employed in accordance with the teachings of the present disclosure individually or in a variety of combinations.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

In order that the disclosure may be well understood, there will now be described embodiments thereof, given by way of example, reference being made to the accompanying drawings, in which:

FIG. 1, a perspective view of a tubular housing of a holder;

FIG. 2, a perspective view of a cage; and

FIG. 3, a perspective view of a cage with an inserted sensor.

### DETAILED DESCRIPTION

The following description is merely exemplary in nature and is not intended to limit the present disclosure, application, or uses.

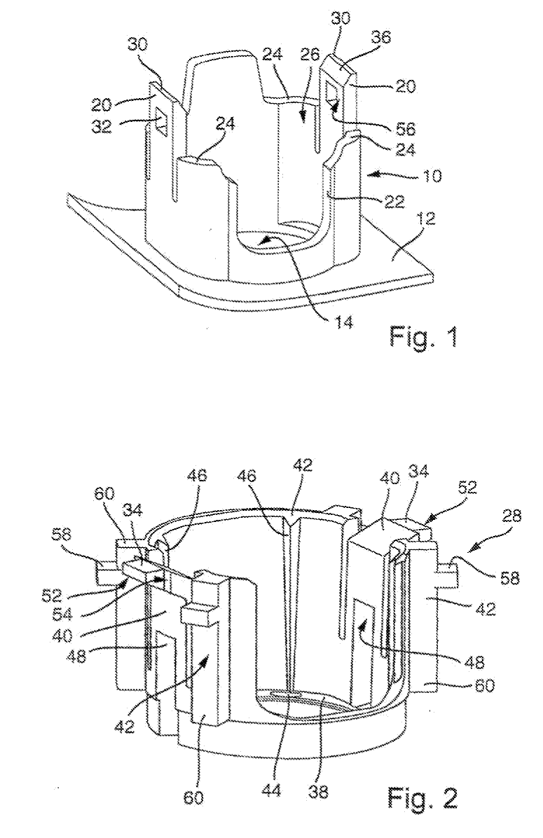

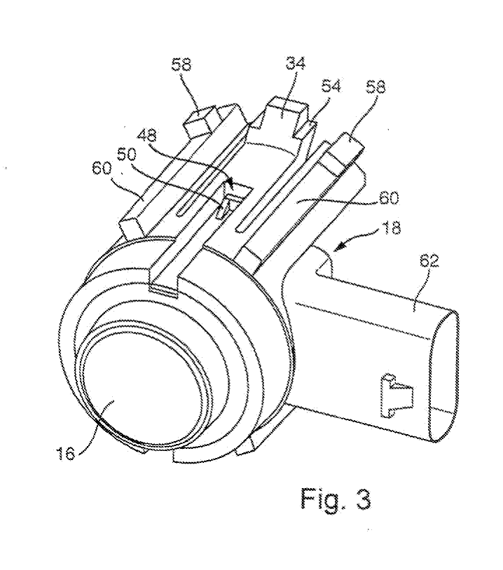

In FIG. 1, a tubular body marked 10 can be seen, which is seated on a fastening portion 12 embodied as an adapter plate. The adapter plate has a shape which matches the shaping of the inner face of a bumper, for instance, of a motor vehicle, so that the adapter plate 12 together with the tubular body 10 can be mounted on the inside of the bumper. The adapter plate 12 has a central opening 14, through which the end having the diaphragm 16 (see FIG. 3) of a sensor 18 can protrude. This opening 14 is surrounded by the tubular body 10, which has two longitudinally extending arms 20 as well as a recess 22. The recess allows an electrical connection 62, which protrudes radially from the sensor 18, to pass through. An insertion opening identified overall by reference numeral 26 is also defined by contact faces 24 of the edge, and through this opening a cage 28, shown in FIG. 2, and the sensor 18 can be inserted into the body 10. The arms 20 have free ends 30, on which receptacles 32 are provided that are engaged by pawls 34 which protrude radially from the cage 28. The arms 20 are designed such that on the free end 30 they are provided with insertion-facilitating bevels 36 and can be elastically bent radially outward slightly.

The cage 28, as seen in FIG. 2, has a bracing ring 38, which when the sensor 18 has been inserted surrounds the end of the sensor 18 that has the diaphragm 16. Beginning at this bracing ring 38, two pivot arms 40 and two cage elements 42 protrude axially. On the side of the bracing ring 38 facing toward the interior, there are knobs 44, which serve the purpose of secure positioning of the sensor 18 in the cage 28. It can also be seen from FIG. 2 that the inside surface of the cage 28 is provided with radially inward-protruding ribs 46, on which the housing of the sensor 18 is braced. These ribs 46 are dimensioned such that the sensor 18 is held in the radial direction in the cage 28 without play.

The pivot arms 40 are designed such that they have a receiving opening 48, which is engaged on the inside by a radially protruding pawl 50 provided on the housing of the sensor 18, once the sensor 18 has been fully inserted into the cage 28. The sensor 18 is then held without play in the radial direction in the cage 28 by the ribs 46 and without play in the axial direction in the cage by the locking of the pawls 50 in the receiving openings 48.

If the cage 28, with the sensor 18 positioned in it, as shown in FIG. 3, is inserted into the tubular body 10, the free ends 52 of the pivot arms 40 are bent radially inward, until the pawls 34 lock into the receptacles 32. The free ends 52 of the pivot arms 40 then snap radially outward again, until a boundary face 54, located laterally next to the pawls 34, rests on the inner face 56 (FIG. 1) of the arms 20. Further pivoting radially outward is no longer possible. This prevents the locked condition of the pawls 50 of the sensor 18 in the receiving opening 48 of the pivot arms 40 from being undone. This locked condition is locked in this way.

Finally, radially outward-protruding insertion limiters 58 are located on the cage elements 42 and, once the cage 28 has been inserted into the body 10, rest on the contact faces 24 and prevent further insertion. In this position of the cage 28 in the tubular body 10, the pawls 34 are snapped into the receptacles 32. Finally, the cage 28 also has radially outward-protruding ribs 60, by way of which the cage 28 is placed in the body 10 in the radial direction without play.

If a sensor is used in the body 10 that has a larger diameter, then radially outward-protruding pawls on the sensor engage the receptacles 32, so that the arms 20 serve the purpose of direct fixation of this sensor. In that case, the cage 28 is not needed. The body 10 can accordingly serve not only to receive a smaller sensor 18 with a cage 28 but also to receive a larger sensor.

By means of different cages 28, different sensors of smaller diameters can be fastened in the same body 10.

It should be noted that the disclosure is not limited to the embodiment described and illustrated as examples. A large variety of modifications have been described and more are part of the knowledge of the person skilled in the art. These and further modifications as well as any replacement by technical equivalents may be added to the description and figures, without leaving the scope of the protection of the disclosure and of the present patent.

What is claimed is:

1. A holder for a sensor (18), in particular an ultrasound sensor for a parking assistance system, having a tubular body (10), into which the sensor (18) is insertable via an insertion opening (26), and having a fastening portion (12), for fastening the holder to a vehicle part, characterized in that between the tubular body (10) and the sensor (18), a cage (28) is provided, which fixes the sensor (18) in both the axial direction and the radial direction in the tubular body (10).

2. The holder as defined by claim 1, characterized in that the tubular body (10) and/or the cage (28) has a recess (22), which is peripherally open toward the insertion opening, for receiving an electrical connection (62) that for instance protrudes radially from the sensor (18).

3. The holder as defined by claim 1, characterized in that the cage (28) has at least one pivot arm (40), extending in the longitudinal direction and having a free end (52); and that the pivot arm (40) has a receiving opening (48) for receiving a pawl (50) that protrudes radially from the sensor (18).

4. The holder as defined by claim 1, characterized in that the cage (28), on its side diametrically opposite the insertion opening (26) of the tubular body (10), has a radially inward-protruding bracing ring (38).

5. The holder as defined by claim 4, characterized in that the region of the sensor (18) having the diaphragm (16) extends through the bracing ring (38) and is braced with a shoulder on the bracing ring (38).

6. The holder as defined by claim 5, characterized in that the bracing ring (38), on its side toward the interior of the cage (28), has retention knobs (44) for the shoulder of the sensor (18).

7. The holder as defined by claim 3, characterized in that the free end (52) of the pivot arm (40) is provided with a radially outward-protruding pawl (34), which is lockable into a receptacle (32) provided on the tubular body (10).

8. The holder as defined by claim 3, characterized in that the free end (52) of the pivot arm (40) is provided with a radially outward-protruding boundary face (54), which comes to rest on the inside face of the tubular body (10).

9. The holder as defined by claim 1, characterized in that the cage (28) has a radially outward-protruding insertion limiter (58), which comes to rest on the edge (24) of the insertion opening (26) of the tubular body (10).

10. The holder as defined by claim 1, characterized in that the cage (28) has radially outward-protruding ribs (60), which extend in the longitudinal direction and rest on the inner wall of the tubular body (10).

11. The holder as defined by claim 1, characterized in that the cage (28) is embodied in one piece.

12. A method for fastening a sensor (18) in a holder, characterized in that a cage (28) as defined by claim 1 is fastened to the sensor (18), and then the cage (28) is locked with the sensor (18) in the holder, thereby assuring the fastening of the sensor (18) in the cage (28).
